(19) United States
(12) Patent Application Publication
(10) Pub. No.: US 2024/0427968 A1
(43) Pub. Date: Dec. 26, 2024

(54) WELLHEAD FATIGUE PREDICTION VIA INTERPOLATION USING CLUSTERED MACHINE LEARNING MODELS AND EXTRAPOLATION USING CLUSTER CENTERS

(71) Applicant: Chevron U.S.A. Inc., San Ramon, CA (US)

(72) Inventors: Yixiong Ma, Houston, TX (US); Shuxing Cheng, Katy, TX (US); Wangming Lu, Katy, TX (US)

(21) Appl. No.: 18/338,972

(22) Filed: Jun. 21, 2023

(51) Int. Cl. G06F 30/27; G06F 30/28

(52) U.S. Cl. CPC G06F 30/27; G06F 30/28

(57) ABSTRACT

Metocean conditions for a wellhead, such as current profile and wave characteristics, are used to determine wellhead fatigue damage rate for the wellhead. The wellhead fatigue damage rate is determined using an interpolation approach or an extrapolation approach. In the interpolation approach, the metocean conditions of the wellhead are input into one of multiple clustered machine learning models to determine the wellhead fatigue damage rate. In the extrapolation approach, a curve is generated to fit cluster centers of the multiple clustered machine learning models, and the wellhead fatigue damage rate is determined based on the curve and the distance between the metocean conditions of the wellhead and null metocean conditions.

### FIELD

The present disclosure relates generally to the field of wellhead fatigue prediction via interpolation using multiple clustered machine learning models and extrapolation using cluster centers of the multiple clustered machine learning models.

### BACKGROUND

Operation of an underwater well (e.g., subsea well) may result in wellhead fatigue damage. Accurate prediction of wellhead fatigue damage is required to make informed decisions on operations of the underwater well. Physical measurements of wellhead fatigue damage is costly and limited to measurement of fatigue damage already incurred from historical operations. Physics-based wellhead fatigue analysis is costly and often overly conservative in predicting wellhead fatigue damage, which may result in unnecessary disconnection of the riser from the wellhead and rig time loss.

### SUMMARY

This disclosure relates to wellhead fatigue prediction. Metocean information for a wellhead, clustered model information, and/or other information may be obtained. The metocean information for the wellhead may characterize metocean conditions for the wellhead. The clustered model information may define multiple clustered machine learning models. The multiple clustered machine learning models may be trained for ranges of metocean conditions. The multiple clustered machine learning models may have cluster centers. Whether the metocean conditions for the wellhead fall within the ranges of metocean conditions for the multiple clustered machine learning models may be determined.

Responsive to the metocean conditions for the wellhead falling within a given range of metocean conditions for a given clustered machine learning model, a wellhead fatigue damage rate for the wellhead may be determined based on the given clustered machine learning model, the metocean conditions for the wellhead, and/or other information. Responsive to the metocean conditions for the wellhead not falling within the ranges of metocean conditions for the multiple clustered machine learning models, the wellhead fatigue damage rate for the wellhead may be determined based on the cluster centers of the multiple clustered machine learning models, a distance between the metocean conditions for the wellhead and null metocean conditions, and/or other information. One or more well operations may be facilitated based on the wellhead fatigue damage rate for the wellhead and/or other information.

A system for wellhead fatigue prediction may include one or more electronic storage, one or more processors and/or other components. The electronic storage may store information relating to a wellhead, information relating to a riser above the wellhead, metocean information, information relating to metocean conditions for the wellhead, clustered model information, information relating to clustered machine learning models, information relating to ranges of metocean conditions for the clustered machine learning models, information relating to cluster centers of the clustered machine learning models, information relating to wellhead fatigue damage rate, information relating to well operations, and/or other information.

The processor(s) may be configured by machine-readable instructions.

Executing the machine-readable instructions may cause the processor(s) to facilitate wellhead fatigue prediction. The machine-readable instructions may include one or more computer program components. The computer program components may include one or more of a metocean component, clustered model component, condition component, interpolation component, extrapolation component, operation component, and/or other computer program components.

The metocean component may be configured to obtain metocean information for a wellhead and/or other information. The metocean information for a wellhead may characterize metocean conditions for the wellhead. In some implementations, the metocean conditions for the wellhead may include current profile and wave characteristics for the wellhead. The current profile for the wellhead may include speed and direction of water movement across a water column along a riser above the wellhead. The wave characteristics for the wellhead may include peak wave period and significant wave height for wave above the water column. In some implementations, values of the metocean conditions for the wellhead may be scaled and dimensionality of the metocean conditions for the wellhead may be reduced.

The clustered model component may be configured to obtain clustered model information and/or other information. The clustered model information may define multiple clustered machine learning models. The multiple clustered machine learning models may be trained for ranges of metocean conditions. The multiple clustered machine learning models may have cluster centers.

The condition component may be configured to determine whether the metocean conditions for the wellhead fall within the ranges of metocean conditions for the multiple clustered machine learning models. In some implementations, determination of whether the metocean conditions for the wellhead fall within the ranges of metocean conditions for the multiple clustered machine learning models may include: determination of distances between the metocean conditions for the wellhead and the cluster centers of the multiple clustered machine learning models; and determination of whether the metocean conditions for the wellhead fall within the ranges of metocean conditions for the multiple clustered machine learning models based on the distances between the metocean conditions for the wellhead and the cluster centers of the multiple clustered machine learning models.

The interpolation component may be configured to, responsive to the metocean conditions for the wellhead falling within a given range of metocean conditions for a given clustered machine learning model, determine a wellhead fatigue damage rate for the wellhead based on the given clustered machine learning model, the metocean conditions for the wellhead, and/or other information.

In some implementations, determination of the wellhead fatigue damage rate for the wellhead based on the given clustered machine learning model and the metocean conditions for the wellhead may include inputting the metocean conditions for the wellhead into the given clustered machine learning model. The given clustered machine learning model may output the wellhead fatigue damage rate. Use of the given clustered machine learning model for the determination of the wellhead fatigue damage rate for the wellhead may enable higher accuracy in wellhead fatigue damage rate prediction than use of a universal machine learning model.

The extrapolation component may be configured to, responsive to the metocean conditions for the wellhead not falling within the ranges of metocean conditions for the multiple clustered machine learning models, determine the wellhead fatigue damage rate for the wellhead based on the cluster centers of the multiple clustered machine learning models, a distance between the metocean conditions for the wellhead and null metocean conditions, and/or other information. In some implementations, the null metocean conditions may include no current and no wave.

In some implementations, determination of the wellhead fatigue damage rate for the wellhead based on the cluster centers of the multiple clustered machine learning models and the distance between the metocean conditions for the wellhead and the null metocean conditions may include: determination of a curve to fit the cluster centers of the multiple clustered machine learning models, the curve defining wellhead fatigue damage rates as a function of distance from the null metocean conditions; and determination of the wellhead fatigue damage rate for the wellhead based on the curve and the distance between the metocean conditions for the wellhead and the null metocean conditions. Use of the curve and the distance between the metocean conditions for the wellhead and the null metocean conditions may enable accurate wellhead fatigue damage rate prediction for the wellhead despite the metocean conditions for the wellhead not being within training data for the multiple clustered machine learning models.

The operation component may be configured to facilitate one or more well operations based on the wellhead fatigue damage rate for the wellhead and/or other information.

These and other objects, features, and characteristics of the system and/or method disclosed herein, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention. As used in the specification and in the claims, the singular form of “a,” “an,” and “the” include plural referents unless the context clearly dictates otherwise.

### BRIEF DESCRIPTION OF THE DRAWINGS

FIG. 1 illustrates an example system for wellhead fatigue prediction.

FIG. 2 illustrates an example method for wellhead fatigue prediction.

FIG. 3 illustrates an example wellhead.

FIG. 4 illustrates an example process for wellhead fatigue prediction.

FIG. 5 illustrates an example process for training clustered machine learning models for wellhead fatigue prediction.

FIG. 6 illustrates an example process for wellhead fatigue prediction using interpolation and extrapolation.

FIG. 7 illustrates example clusters and input data for wellhead fatigue prediction.

FIG. 8A illustrates example cluster centers for wellhead fatigue prediction.

FIG. 8B illustrates example curves that fit the cluster centers for wellhead fatigue prediction.

### DETAILED DESCRIPTION

The present disclosure relates to wellhead fatigue prediction. Metocean conditions for a wellhead, such as current profile and wave characteristics, are used to determine wellhead fatigue damage rate for the wellhead. The wellhead fatigue damage rate is determined using an interpolation approach or an extrapolation approach. In the interpolation approach, the metocean conditions of the wellhead are input into one of multiple clustered machine learning models to determine the wellhead fatigue damage rate. In the extrapolation approach, a curve is generated to fit cluster centers of the multiple clustered machine learning models, and the wellhead fatigue damage rate is determined based on the curve and the distance between the metocean conditions of the wellhead and null metocean conditions.

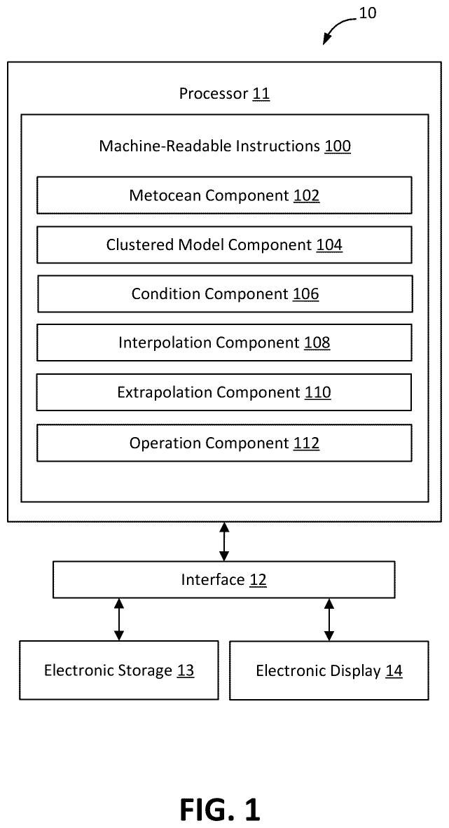

The methods and systems of the present disclosure may be implemented by a system and/or in a system, such as a system 10 shown in FIG. 1. The system 10 may include one or more of a processor 11, an interface 12 (e.g., bus, wireless interface), an electronic storage 13, an electronic display 14, and/or other components. Metocean information for a wellhead, clustered model information, and/or other information may be obtained by the processor 11. The metocean information for the wellhead may characterize metocean conditions for the wellhead. The clustered model information may define multiple clustered machine learning models. The multiple clustered machine learning models may be trained for ranges of metocean conditions. The multiple clustered machine learning models may have cluster centers. Whether the metocean conditions for the wellhead fall within the ranges of metocean conditions for the multiple clustered machine learning models may be determined by the processor 11.

Responsive to the metocean conditions for the wellhead falling within a given range of metocean conditions for a given clustered machine learning model, a wellhead fatigue damage rate for the wellhead may be determined by the processor 11 based on the given clustered machine learning model, the metocean conditions for the wellhead, and/or other information. Responsive to the metocean conditions for the wellhead not falling within the ranges of metocean conditions for the multiple clustered machine learning models, the wellhead fatigue damage rate for the wellhead may be determined by the processor 11 based on the cluster centers of the multiple clustered machine learning models, a distance between the metocean conditions for the wellhead and null metocean conditions, and/or other information. One or more well operations may be facilitated by the processor 11 based on the wellhead fatigue damage rate for the wellhead and/or other information.

The electronic storage 13 may include one or more electronic storage media that electronically stores information. The electronic storage 13 may store software algorithms, information determined by the processor 11, information received remotely, and/or other information that enables the system 10 to function properly. For example, the electronic storage 13 may store information relating to a wellhead, information relating to a riser above the wellhead, metocean information, information relating to metocean conditions for the wellhead, clustered model information, information relating to clustered machine learning models, information relating to ranges of metocean conditions for the clustered machine learning models, information relating to cluster centers of the clustered machine learning models, information relating to wellhead fatigue damage rate, information relating to well operations, and/or other information.

The electronic display 14 may refer to an electronic device that provides visual presentation of information. The electronic display 14 may include a color display and/or a non-color display. The electronic display 14 may be configured to visually present information. The electronic display 14 may present information using/within one or more graphical user interfaces. For example, the electronic display 14 may present information relating to a wellhead, information relating to a riser above the wellhead, metocean information, information relating to metocean conditions for the wellhead, clustered model information, information relating to clustered machine learning models, information relating to ranges of metocean conditions for the clustered machine learning models, information relating to cluster centers of the clustered machine learning models, information relating to wellhead fatigue damage rate, information relating to well operations, and/or other information.

A well may refer to a hole or a tunnel in the ground. A well may be drilled in one or more directions. For example, a well may be a vertical well, a horizontal well, a deviated well, and/or other type of well. A well may include one or more vertical sections, one or more horizontal sections, and/or other types of sections. A well may be drilled in the ground for exploration and/or recovery of natural resources in the ground. For example, a well may be drilled in the ground to aid in extraction of petrochemical fluid (e.g., oil, gas, petroleum, fossil fuel). Application of the present disclosure to other types of wells and wells drilled for other purposes are contemplated.

Equipment may be installed at the well to facilitate well operations. For example, a wellhead may be installed at the top of the well. A wellhead may refer to one or more components at the top/surface of the well that provides structural and/or pressure-containing interface for drilling and production equipment. For example, a wellhead may include spools, valves, and/or adapters that provide pressure control of a production well. A wellhead may allow for connection of various equipment to the well for production. For example, for an underwater well (e.g., a subsea well), one end of a riser may be connected to a wellhead of a well and the other end of the riser may be connected to a surface facility, such as a platform, floating production storage, and/or offloading vessels. A riser may include one or more pipe that delivers fluid between the well/wellhead and the surface facility. A riser may include one or more flexible components, floatation components, and/or components to facilitate use of the riser in an underwater environment.

Movement of water around the riser may place force on the riser to push the riser out of its neutral position above the wellhead. Movement of water around the riser may cause shifting, vibration, and/or other movement of the riser. Shifting, vibration, and/or other movement of the riser may fatigue/weaken the wellhead connected to the riser. Wellhead fatigue damage may accumulate over a period of time. Too much wellhead fatigue damage may result in failure or breakage of the wellhead.

The wellhead fatigue damage rate may refer to a rate at which fatigue damage is accumulated at the wellhead. The wellhead fatigue damage rate may refer to a rate at which the wellhead is experiencing fatigue damage. The wellhead fatigue damage rate may be used to make operational decisions for the well/wellhead. For example, the wellhead fatigue damage rate may be used to determine whether an operation should be discontinued from wellhead fatigue damage perspective and to ensure operational safety.

Wellhead fatigue damage rate may be measured via physical measurement with sensors installed on the equipment sitting on top of wellhead, such as blowout preventer (BOP). But such an approach is costly and limited to measurement of fatigue damage already incurred from historical operations. Wellhead fatigue damage rate may be estimated via physics-based fatigue analysis. However, physics-based wellhead fatigue analysis is costly and often overly conservative in predicting wellhead fatigue damage, which may result in unnecessary disconnection of the riser from the wellhead and rig time loss.

The present disclosure provides a tool/technique to accurately assess wellhead fatigue damage (e.g., wellhead fatigue damage rate, wellhead fatigue damage accumulation). The tool/technique of the present disclosure is less costly than physical measurement approach while providing accuracy needed to make operational decisions for the well/wellhead. The tool/technique of the present disclosure may be deployed and used by operators (e.g., engineers, rig team) without expertise in riser movement analysis and/or wellhead fatigue analysis. The tool/technique of the present disclosure may be used in a real-time manner and facilitate operators to make more intelligent and confident operational decisions for the well/wellhead in a timely manner.

The present disclosure utilizes multiple clustered machine learning modeled trained on measured wellhead fatigue damage rate as the target and metocean conditions as the features. The clustered machine learning models provide more accurate output when the input data is similar to the training data for the clustered machine learning models. Output of the clustered machine learning models may be less accurate when the input data is significantly different from the training data for the clustered machine learning models. In such cases, the present disclosure utilizes an extrapolation scheme (workflow) that incorporates cluster centers of the clustered machine learning models to predict wellhead fatigue damage rate.

The present disclosure solves engineering challenges for wellhead fatigue prediction by (1) using clustered machine learning models to improve prediction performance when input data is within ranges for which the clustered machine learning models have been trained, and (2) providing an extrapolation scheme when the input data is outside the ranges for which the clustered machine learning models have been trained.

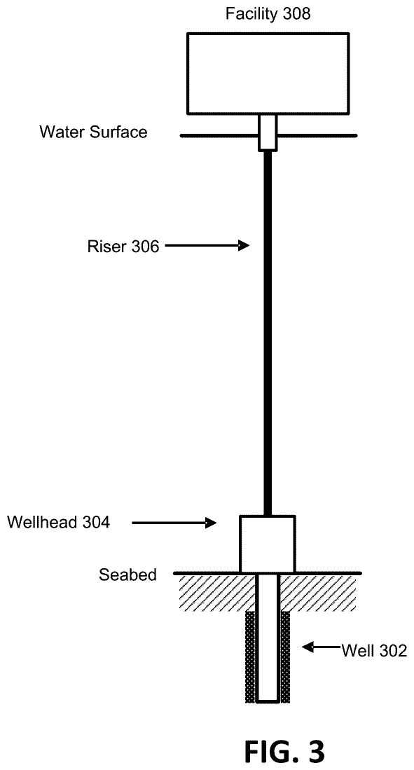

FIG. 3 illustrates an example wellhead 304 for a well 302. The well 302 may be located under the water. For example, the well 302 may be located under the ocean/sea. The wellhead 304 may be installed on the well 302, and a riser 306 may be connected to the wellhead 304. The riser 306 may provide a connection through which fluid may flow between the well 302/wellhead 304 and a facility 308 at/above the water surface. The well 302 and/or the riser 306 may include other components not shown in FIG. 3 (e.g., blowout preventer, lower marine riser package, flexible joint, slick joint, buoyancy joint, water current sensor). For example, water current sensors may be placed along the riser 306 to measure the speed and direction of water around the riser 306. Movement sensors may be positioned along the wellhead 304, the riser 306, and/or other components to measure the movement of equipment connected to the well 302. Wellhead fatigue damage rate may be estimated/calculated based on the movement of the equipment connected to the well 302 and/or other information.

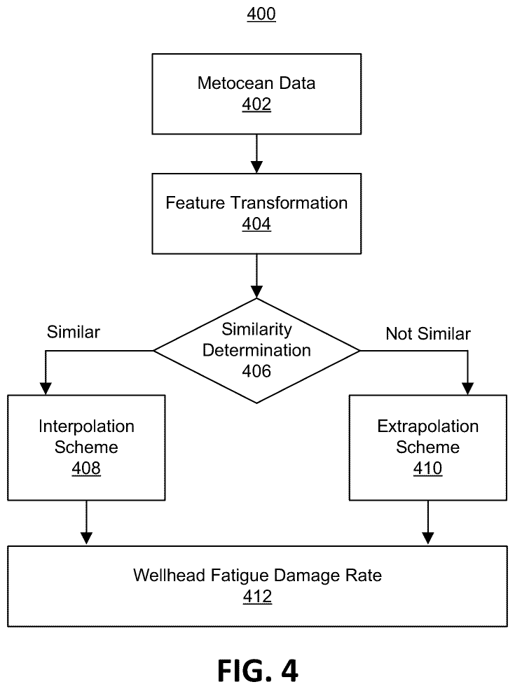

FIG. 4 illustrates an example process 400 for wellhead fatigue prediction. The process 400 may be used to determine (e.g., calculate, estimate, predict) a wellhead fatigue damage rate for a wellhead based on metocean conditions for the wellhead. In some implementations, additional and/or alternative information may be used to determine the wellhead fatigue damage rate for the wellhead. For example, information relating to the environment and/or the equipment (e.g., riser tension, rig type, wellhead type, component type) may be used to determine the wellhead fatigue damage rate for the wellhead. For instance, in addition to and/or alternative to metocean conditions for the wellhead, information relating to the environment and/or the equipment may be used to train clustered machine learning models. The information relating to the environment and/or the equipment may be used in interpolation or extrapolation schemes to determine the wellhead fatigue damage rate for the wellhead. Use of other information is contemplated.

The process 400 may be used to determine the wellhead fatigue damage rate for one or more moments in time (e.g., time point(s), time duration(s). The process 400 may be used to determine the wellhead fatigue damage rate for the moment(s) in time corresponding to the metocean conditions for the wellhead. For example, the process 400 may be used to determine the past wellhead fatigue damage rate for the wellhead based on the past metocean conditions for the wellhead. The process 400 may be used to determine the present/real-time wellhead fatigue damage rate for the wellhead based on the present/real-time metocean conditions for the wellhead. The process 400 may be used to determine the forecasted wellhead fatigue damage rate for the wellhead based on the forecasted metocean conditions for the wellhead.

In the process 400, metocean data 402 for a wellhead may be obtained. The metocean data 402 may include information relating to metocean conditions for the wellhead. For example, the metocean data 402 may include information characterizing metocean conditions for the wellhead. The metocean data 402 may include information relating to metocean conditions corresponding to one or more moments in time. Feature transformation 404 may be performed on the metocean data 402. The feature transformation 404 may change the form of the metocean data 402 while keeping the underlying information in the metocean data 402 intact. The feature transformation 404 may transform the form of the metocean data 402 to normal distribution.

Similarity determination 406 may include determination of whether the metocean data 402 is similar to training data used to train clustered machine learning models. Different clustered machine learning models may be trained using different ranges of metocean conditions (e.g., different clusters of training data), and the similarity between the metocean data 402 and different ranges of metocean conditions, for which the clustered machine learning models have been trained, may be determined. For example, cluster similarity scores for the metocean data 402 may be computed. The cluster similarity scores may indicate similarity between the metocean data 402 and the different ranges of metocean conditions used to train the different clustered machine learning models.

Based on the metocean data 402 being similar to the training data used to train a particular clustered machine learning model (e.g., based on the cluster similarity score satisfying a cluster similarity score threshold for the particular clustered machine learning model), an interpolation scheme 408 may be used to determine the wellhead fatigue damage rate 412 for the wellhead. Based on the metocean data 402 not being similar to the training data used to train any clustered machine learning models (e.g., based on the cluster similarity score not satisfying any cluster similarity score thresholds), an extrapolation scheme 410 may be used to determine the wellhead fatigue damage rate 412 for the wellhead.

In the interpolation scheme 408, the particular clustered machine learning model that was trained using training data similar to the metocean data 402 may be used to determine the wellhead fatigue damage rate 412 for the wellhead. For example, the metocean data 402 may be input into the particular clustered machine learning model, which may then output the wellhead fatigue damage rate 412 for the wellhead.

In the extrapolation scheme 410, the wellhead fatigue damage rate 412 for the wellhead may be determined by using (1) cluster centers of the multiple clustered machine learning models, and (2) the distance between the metocean conditions for the wellhead (included in the metocean data 402) and null metocean conditions. The cluster centers of the multiple clustered machine learning models may be associated with values of wellhead fatigue damage rate. The null metocean conditions may include no/zero wave and no/zero current for the wellhead. The null metocean conditions may be associated with no wellhead fatigue damage rate/zero value of wellhead fatigue damage rate.

A curve may be generated to fit the cluster centers of the multiple clustered machine learning models. The curve may define different values of wellhead fatigue damage rate as a function of distance from the null metocean conditions. The value of the curve for the distance between the metocean conditions for the wellhead and the null metocean conditions may be output as the wellhead fatigue damage rate 412 for the wellhead.

The process 400 provides a hybrid approach in which (1) wellhead fatigue damage rates are determined using clustered machine learning models when the input data is similar to the training data for the clustered machine learning models and (2) wellhead fatigue damage rates are extrapolated based on cluster centers of the clustered machine learning models and the distance of the input data from null metocean conditions when the input data is not similar to the training data for the clustered machine learning models. The process 400 enables accurate prediction of wellhead fatigue damage rate even when the input data is not similar to the training data for the clustered machine learning models. The predictive capability of the present disclosure is extended to enable wellhead fatigue prediction even when the input data goes beyond the training data.

For example, it is desirable to predict wellhead fatigue damage rate in severe metocean conditions where extreme wave/current conditions occur. However, no/little wellhead fatigue data may exist for such conditions as prediction of such severe metocean condition may prompt disconnection of the riser from the wellhead to prevent damage to the wellhead. Machine learning models trained using training data that do not include severe metocean conditions may provide inaccurate wellhead fatigue predictions for severe metocean conditions. The present disclosure overcomes this shortcoming by using the extrapolation scheme 410 for such input while using the interpolation scheme 408 when the input falls within ranges of the training data.

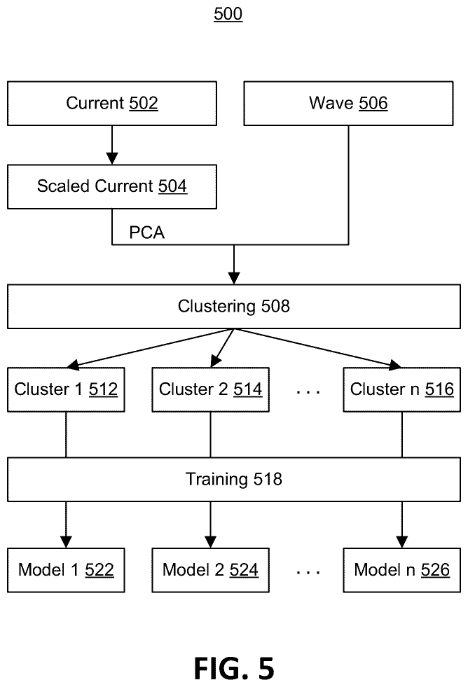

FIG. 5 illustrates an example process 500 for training clustered machine learning models for wellhead fatigue prediction. The training data may include current 502, wave 506, and corresponding wellhead fatigue damage rates for a wellhead. The current 502 may include current speed and/or current direction. The current 502 may include current speed and/or current direction at different depths. The current 502 may be scaled to generate scaled current 504. For example, the speed of the current 502 may be scaled (e.g., between zero and one, between other range) using a scaler. The speed of the current 502 may be scaled to a normal distribution. The dimensionality of the scaled current 504 may be reduced via principal component analysis (PCA) (e.g., reduce the current speed at different depths into a certain number of features), and combined with the wave 506 for clustering 508.

One or more clustering models/algorithms (e.g., unsupervised clustering model/algorithm) may be used to cluster the training data into multiple clusters. For example, the training data may be clustered into n different clusters. Individual clusters may correspond to different ranges of the training data (e.g., different ranges of metocean conditions, different ranges of current speed, current direction, and wave). The clusters of training data may be used for training 518 of different clustered machine learning models. Current, wave and corresponding wellhead fatigue damage rates for a wellhead may be used to train the clustered machine learning models. The clustered machine learning models may be trained to output wellhead fatigue damage rate based on current and wave being input in the clustered machine learning models. The clustered machine learning models may be trained using other information as input, such as information relating to the environment and/or the equipment.

A clustered machine learning model may refer to a machine learning model trained using a cluster of training data. Rather than training a universal machine learning model for all ranges of input data, different clustered machine learning models may be trained for different ranges of input data. For example, a cluster 1 512 of the training data may be used to train a model 1 522, a cluster 2 514 of the training data may be used to train a model 2 522, and a cluster n 516 of the training data may be used to train a model n 526. Individual clustered machine learning model may be more accurate in wellhead fatigue damage rate prediction for the corresponding range of input data than a universal machine learning model trained for all ranges of input data.

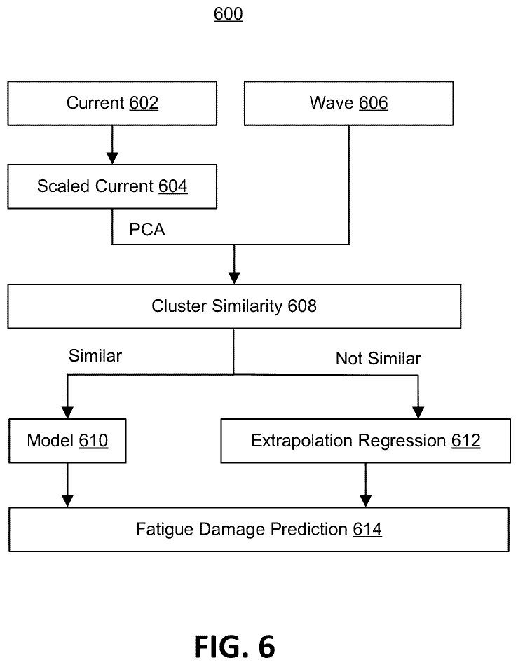

FIG. 6 illustrates an example process 600 for wellhead fatigue prediction using interpolation and extrapolation. The input data may include current 602 and wave 606 for a wellhead. The input data may include other types of information, such as information relating to the environment and/or the equipment. The current 602 may include current speed and/or current direction. The current 602 may include current speed and/or current direction at different depths. The current 602 may be scaled to generate scaled current 604. For example, the speed of the current 602 may be scaled (e.g., between zero and one, between other range) using a scaler. The speed of the current 602 may be scaled to a normal distribution. The dimensionality of the scaled current 604 may be reduced via principal component analysis (PCA) (e.g., reduce the current speed at different depths into a certain number of features), and combined with the wave 606 for cluster similarity 608 determination.

The cluster similarity 608 determination may include determination of whether and/or to what extent the current 602 and the wave 606 of the input data are similar to a cluster of training data used to train multiple clustered machine learning models. The cluster similarity 608 determination may include determination of whether the current 602 and the wave 606 falls within ranges of metocean conditions used to train different clustered machine learning models. For example, cluster similarity scores for the current 602 and the wave 606 of the input data may be computed, with individual cluster similarity score indicating how similar the current 602 and the wave 606 are to individual clusters of training data used to train multiple clustered machine learning models. The cluster similarity scores may indicate how far the current 602 and the wave 606 are from the center of clusters of training data used to train multiple clustered machine learning models. The cluster similarity scores may be used as a proxy to quantify the relative location of the input data in the high dimensional space constructed using clustered training data.

If the current 602 and the wave 606 of the input data are similar to a cluster of training data for a particular clustered machine learning model, the particular clustered machine learning model (a model 610) may be used for fatigue damage prediction 614. If the current 602 and the wave 606 of the input data fall within the range of input data for which the model 610 was trained, the model 610 may be used for the fatigue damage prediction 614. The current 602 and the wave 606 of the input data may be input into the model 610, and the model 610 may output the wellhead fatigue damage rate.

If the current 602 and the wave 606 of the input data are not similar to a cluster of training data for any clustered machine learning model, extrapolation regression 612 may be used for the fatigue damage prediction 614. If the current 602 and the wave 606 of the input data do not fall within the range of input data for any clustered machine learning models, the extrapolation regression 612 may be used for the fatigue damage prediction 614. The distance between the current 602 and the wave 606 of the input data and zero current and zero wave, and a curve generated to fit the cluster centers of the multiple clustered machine learning models may be used to determine the wellhead fatigue damage rate.

Referring back to FIG. 1, the processor 11 may be configured to provide information processing capabilities in the system 10. As such, the processor 11 may comprise one or more of a digital processor, an analog processor, a digital circuit designed to process information, a central processing unit, a graphics processing unit, a microcontroller, an analog circuit designed to process information, a state machine, and/or other mechanisms for electronically processing information. The processor 11 may be configured to execute one or more machine-readable instructions 100 to facilitate wellhead fatigue prediction. The machine-readable instructions 100 may include one or more computer program components. The machine-readable instructions 100 may include one or more of a metocean component 102, clustered model component 104, condition component 106, interpolation component 108, extrapolation component 110, operation component 112, and/or other computer program components.

The metocean component 102 may be configured to obtain metocean information for a wellhead and/or other information. Obtaining metocean information may include one or more of accessing, acquiring, analyzing, determining, examining, generating, identifying, loading, locating, measuring, opening, receiving, retrieving, reviewing, selecting, storing, and/or otherwise obtaining the metocean information. The metocean component 102 may obtain metocean information from one or more locations. For example, the metocean component 102 may obtain metocean information from a storage location, such as the electronic storage 13, electronic storage of a device accessible via a network, and/or other locations. The metocean component 102 may obtain metocean information from one or more hardware components (e.g., a computing device) and/or one or more software components (e.g., software running on a computing device). In some implementations, the metocean information may be obtained from one or more users. For example, a user may interact with a computing device to input the metocean information (e.g., upload the metocean information, specify the metocean information).

The metocean information for a wellhead may characterize metocean conditions for the wellhead. Metocean conditions for a wellhead may refer to wind, wave, climate, and/or other environmental conditions that affect wellhead and/or water around/surrounding/above the wellhead. Metocean conditions for a wellhead may refer to conditions within the whole water depth above and/or near the wellhead, such as the water column above the wellhead. Metocean conditions for a wellhead may refer to conditions at the surface of the water and under the surface of the water. For example, metocean conditions for a wellhead may include conditions relating to water depth, waves, currents, tide and surge variations, and/or other environmental conditions around/surrounding/above the wellhead.

The metocean information may characterize metocean conditions at different depths. The metocean information may characterize changes in the metocean conditions through depth. The metocean information may characterize a metocean condition by defining, describing, identifying, quantifying, reflecting, setting forth, and/or otherwise characterizing the current profile. The metocean information may characterize a metocean condition by defining, describing, identifying, quantifying, reflecting, setting forth, and/or otherwise characterizing one or more of value, property, quality, quantity, attribute, feature, and/or other aspects of the metocean condition. The metocean information may include information that characterizes the type and/or the value of the metocean condition. The metocean information may include information from which the type and/or the value of the metocean condition may be determined. Other types of metocean information are contemplated.

In some implementations, the metocean conditions for the wellhead may include current profile and wave characteristics for the wellhead. The current profile for the wellhead may include speed and direction of water movement across a water column along a riser above the wellhead. The current profile may outline, describe, and/or represent the speed and/or direction of water movement across the water column along the riser. The current profile may include a profile of water movement speed and/or direction along the entire water column or for one or more parts of the water column. For example, the current profile may include a profile of speed and/or direction of water movement from the water surface to the mudline/seabed.

Wave characteristics for the wellhead may include characteristics of wave above the wellhead. Wave characteristics for the wellhead may include physical features of the wave above the wellhead. For example, the wave characteristics for the wellhead may include peak wave period (Tp) and significant wave height (Hs) for wave above the water column along the riser above the wellhead. The peak wave period (Tp) and the significant wave height (Hs) may define physical features of the wave.

In some implementations, the metocean information may include time series data. The time series data may indicate the metocean conditions for the wellhead at different moments. Rather than obtaining the metocean conditions for a specific moment in time, the metocean conditions may be obtained for different moments in time. The metocean information may characterize changes in the metocean conditions through time.

In some implementations, the metocean information may characterize real-time metocean conditions. The metocean information may characterize present metocean conditions at different depths. Real-time metocean conditions may include metocean conditions that have been measured within a threshold amount of time (e.g., current profile and/or wave characteristics measured within the past day/part of the past day).

In some implementations, the metocean information may characterize historical metocean conditions. The metocean information may characterize past metocean conditions at different depths. Historical metocean conditions may include metocean conditions that have been measured past a threshold amount of time (e.g., current profile and/or wave characteristics measured more than a day, a week, a month, or a year ago).

In some implementations, the metocean information may characterize a forecast of metocean conditions. The metocean information may characterize forecasted metocean conditions at different depths. Forecasted metocean conditions may include metocean conditions that have been predicted in the future based on real-time metocean conditions, historical metocean conditions, and/or other information. Forecasted metocean conditions may include metocean conditions that have been predicted for a future duration of time (e.g., current profile and/or wave characteristics predicted for the next hour, the next day, the next few days, the next week).

In some implementations, values of the metocean conditions for the wellhead may be scaled and dimensionality of the metocean conditions for the wellhead may be reduced. For example, values of metocean conditions (e.g., current profile and/or wave characteristics) for the wellhead may be scaled between zero and one, or between other ranges, using a scaler. The values of metocean conditions may be scaled to a normal distribution. The dimensionality of the metocean conditions for the wellhead may be reduced via principal component analysis and/or other analysis/technique.

The clustered model component 104 may be configured to obtain clustered model information and/or other information. Obtaining clustered model information may include one or more of accessing, acquiring, analyzing, determining, developing, examining, generating, identifying, loading, locating, opening, preparing, receiving, retrieving, reviewing, selecting, storing, and/or otherwise obtaining the clustered model information. The clustered model component 104 may obtain clustered model information from one or more locations. For example, the clustered model component 104 may obtain clustered model information from a storage location, such as the electronic storage 13, electronic storage of a device accessible via a network, and/or other locations. The clustered model component 104 may obtain clustered model information from one or more hardware components (e.g., a computing device) and/or one or more software components (e.g., software running on a computing device).

The clustered model information may define multiple clustered machine learning models. A clustered machine learning model may refer to a machine learning model trained using a cluster of training data. A clustered machine learning model may refer to a machine learning model trained to provide output for a range of input. A clustered machine learning model may refer to a machine learning model trained to provide output for a range of metocean conditions. The range of metocean conditions for which the clustered machine learning model is trained to provide output may depend on the training data used to train the machine learning mode. The range of metocean conditions for which the clustered machine learning model is trained to provide output may be same as or similar to the range of metocean conditions in the training data used to train the clustered machine learning model. The training data used to train the clustered machine learning models may include measured, calculated, and/or simulated data from the same well in which the wellhead fatigue damage rate is being determined, from one or more different wells, from the same type of well as the well in which the wellhead fatigue damage rate is being determined, and/or one or more different types of wells.

The clustered model information may define a clustered machine learning model by including information that defines one or more content, qualities, attributes, features, and/or other aspects of the clustered machine learning model. For example, the clustered model information may define a clustered machine learning model by including information that makes up the layers, connections between the layers, weights, and/or other characteristics of the clustered machine learning model. Other types of clustered model information are contemplated.

The multiple clustered machine learning models may be trained for ranges of metocean conditions. Different clustered machine learning models may be trained for different ranges of metocean conditions. For example, individual clustered machine learning models may be trained for different clusters of metocean conditions. Individual clustered machine learning models may be trained using different clusters of metocean conditions. The multiple clustered machine learning models may have cluster centers. Individual clustered machine learning models may have different cluster centers. A cluster center of a clustered machine learning model may refer to a point that represents the center of range/cluster of metocean conditions for which the clustered machine learning model has been trained. A cluster center of a clustered machine learning model may refer to a point that represents the center of metocean conditions that have been used to train the clustered machine learning model.

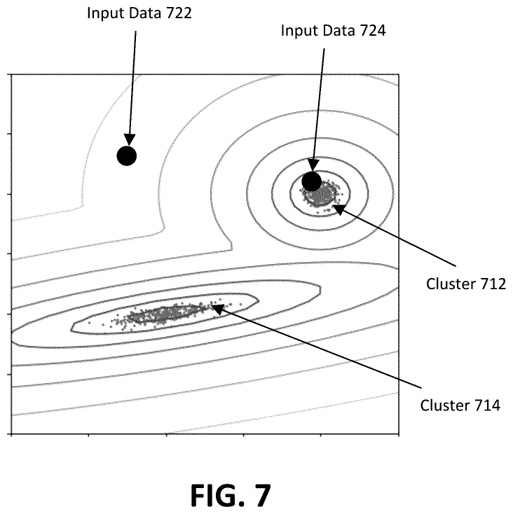

For example, FIG. 7 illustrates two clusters of training data used to train clustered machine learning models. Individual points shown in FIG. 7 may correspond to a particular part of the training data (e.g., particular metocean conditions, particular combination of current profile and wave characteristics). The training data may form two clusters 712, 714. Different clusters may be used to train different clustered machine learning models. For example, the cluster 712 may be used to train one clustered machine learning model and the cluster 714 may be used to train another clustered machine learning model.

The condition component 106 may be configured to determine whether the metocean conditions for the wellhead fall within the ranges of metocean conditions for the multiple clustered machine learning models. Determining whether the metocean conditions for the wellhead fall within the ranges of metocean conditions for the multiple clustered machine learning models may include ascertaining, approximating, calculating, establishing, estimating, finding, identifying, obtaining, quantifying, and/or otherwise determining whether the metocean conditions for the wellhead fall within the ranges of metocean conditions for the multiple clustered machine learning models. Determining whether the metocean conditions for the wellhead fall within the ranges of metocean conditions for the multiple clustered machine learning models may include determining whether the metocean conditions for the wellhead fall within the range of metocean conditions for any of the multiple clustered machine learning models. Determining whether the metocean conditions for the wellhead fall within the ranges of metocean conditions for the multiple clustered machine learning models may include identifying the clustered machine learning model with the range of metocean conditions that covers the metocean conditions for the wellhead. Determining whether the metocean conditions for the wellhead fall within the ranges of metocean conditions for the multiple clustered machine learning models may include determining that the metocean conditions for the wellhead do not fall within any ranges of metocean conditions for any clustered machine learning models.

The condition component 106 may be configured to determine, given the metocean conditions for the wellhead, whether any of the clustered machine learning models may be used to determine the wellhead fatigue damage rate for the wellhead.

The condition component 106 may be configured to determine, given the metocean conditions for the wellhead, which of the clustered machine learning models may be used to determine the wellhead fatigue damage rate for the wellhead. The condition component 106 may be configured to determine, given the metocean conditions for the wellhead, that none of the clustered machine learning models may be used to determine the wellhead fatigue damage rate for the wellhead.

The condition component 106 may be configured to determine whether the metocean conditions for the wellhead are similar to the training data used to train the clustered machine learning models. The condition component 106 may be configured to determine whether the metocean conditions for the wellhead fall within or are near the clusters of training data used to train the clustered machine learning models.

For example, referring to FIG. 7, two input data 722, 724 for wellhead fatigue prediction may be obtained. The input data 722, 724 may include different metocean conditions for a wellhead. The condition component 106 may be configured to determine whether the metocean conditions in the input data 722, 724 fall within the ranges of metocean conditions for the multiple clustered machine learning models. For example, the condition component 106 may be configured to determine whether the metocean conditions in the input data 722, 724 fall within or are near the clusters 712, 714 of training data used to train two clustered machine learning models.

If the input data 722, 724 fall within or are near a cluster of training data used to train a particular clustered machine learning model, the particular clustered machine learning model may be used to determine the wellhead fatigue damage rate for the wellhead from the input data 722, 724. If the input data 722, 724 to not fall within or are far from any clusters of training data used to train any clustered machine learning models, then the cluster centers of the clustered machine learning models may be used to determine the wellhead fatigue damage rate for the wellhead from the input data 722, 724.

For example, in FIG. 7, the input data 722 may not fall within and may be far from the cluster 712 and the cluster 714. Based on the input data 722 not falling within and being far from the cluster 712 and the cluster 714, the clustered machine learning models trained using the cluster 712 and the cluster 714 may not be used to determine the wellhead fatigue damage rate for the wellhead. Instead, the cluster centers of the clustered machine learning models may be used to determine the wellhead fatigue damage rate for the wellhead from the input data 722. On the other hand, the input data 724 may fall within or may be near the cluster 712. Based on the input data 724 falling within or being near the cluster 712, the clustered machine learning model trained using the cluster 712 may be used to determine the wellhead fatigue damage rate for the wellhead from the input data 724.

In some implementations, determination of whether the metocean conditions for the wellhead fall within the ranges of metocean conditions for the multiple clustered machine learning models may include: determination of distances between the metocean conditions for the wellhead and the cluster centers of the multiple clustered machine learning models; and determination of whether the metocean conditions for the wellhead fall within the ranges of metocean conditions for the multiple clustered machine learning models based on the distances between the metocean conditions for the wellhead and the cluster centers of the multiple clustered machine learning models.

For example, referring to FIG. 7, the distances between the input data 724 and the cluster centers of the cluster 712 and the cluster 714 may be determined. Whether the metocean conditions for the wellhead fall within the range of metocean conditions for the clustered machine learning model trained using the cluster 712 may be determined based on the distance between the input data 724 and the cluster center of the cluster 712. Whether the metocean conditions for the wellhead fall within the range of metocean conditions for the clustered machine learning model trained using the cluster 714 may be determined based on the distance between the input data 724 and the cluster center of the cluster 712. For instance, the metocean conditions of the input data 724 may be determined to fall within the range of metocean conditions for the clustered machine learning model trained using the cluster 712 based on the distance between the input data 724 and the cluster center of the cluster 712. The metocean conditions of the input data 724 may be determined to not fall within the range of metocean conditions for the clustered machine learning model trained using the cluster 714 based on the distance between the input data 724 and the cluster center of the cluster 714. Based on the distances between the input data 722 and the cluster centers of the clusters 712, 714, the metocean conditions of the input data 722 may be determined to not fall within the range of metocean conditions for the clustered machine learning model trained using the cluster 712 or the cluster 714.

In some implementations, the distances between the metocean conditions for the wellhead and the cluster centers of the multiple clustered machine learning models may be determined as cluster similarity scores, and whether the metocean conditions for the wellhead fall within the ranges of metocean conditions for the multiple clustered machine learning models may be determined based on whether the cluster similarity scores satisfy a cluster similarity score threshold. The cluster similarity score may be compared with the same or different cluster similarity score thresholds for different input data and/or for different clustered machine learning models.

The interpolation component 108 may be configured to, responsive to the metocean conditions for the wellhead falling within a given range of metocean conditions for a given clustered machine learning model, determine a wellhead fatigue damage rate for the wellhead based on the given clustered machine learning model, the metocean conditions for the wellhead, and/or other information. Determining a wellhead fatigue damage rate may include ascertaining, approximating, calculating, establishing, estimating, finding, identifying, obtaining, quantifying, selecting, setting, and/or otherwise determining the wellhead fatigue damage rate. Determining a wellhead fatigue damage rate may include determining the value of the wellhead fatigue damage rate. The value of the wellhead fatigue damage rate for the wellhead may be determined based on the metocean conditions for the wellhead and/or other information. The value(s) and/or types of the metocean conditions for the wellhead may be used to determine the value(s) of wellhead fatigue damage rate for the wellhead. The value(s) and/or types of the metocean conditions for the wellhead for a particular moment may be used to determine the value(s) of wellhead fatigue damage rate for the wellhead for the particular moment.

In some implementations, the wellhead fatigue damage rate may be determined as a percentage value and/or other values. For example, the wellhead fatigue damage rate may be determined as a percentage of allowable damage of the wellhead. For instance, an undamaged or new wellhead may have started with 100% allowable damage. A wellhead fatigue damage rate may be determined as how much of the allowable damage will be accumulated at the wellhead for a particular duration of time (e.g., 3% for 48-hour period).

Responsive to the metocean conditions for the wellhead falling within a range of metocean conditions for a clustered machine learning model, the clustered machine learning model may be used to determine the wellhead fatigue damage rate for the wellhead. For example, based on the metocean conditions for the wellhead being similar to the training data used to train a clustered machine learning model and/or the metocean conditions for the wellhead failing within or being near a cluster of training data used to train the clustered machine learning model, the clustered machine learning model may be used to determine the wellhead fatigue damage rate for the wellhead. The clustered machine learning model that was trained with training data that is most similar to the metocean conditions for the wellhead may be used to determine the wellhead fatigue damage rate for the wellhead. The metocean conditions for the wellhead may be input into the clustered machine learning model to determine the wellhead fatigue damage rate for the wellhead. Based on the metocean conditions for the wellhead being input into the clustered machine learning model, the clustered machine learning model may output the wellhead fatigue damage rate for the wellhead and/or information from which the wellhead fatigue damage rate for the wellhead may be determined. Use of the clustered machine learning model in determining the wellhead fatigue damage rate for the wellhead may enable higher accuracy in wellhead fatigue damage rate prediction than use of a universal machine learning model. That is, individual clustered machine learning model may be more accurate in wellhead fatigue damage rate prediction for the corresponding range of metocean conditions than a universal machine learning model trained for all ranges of metocean conditions.

The extrapolation component 110 may be configured to, responsive to the metocean conditions for the wellhead not falling within the ranges of metocean conditions for the multiple clustered machine learning models, determine the wellhead fatigue damage rate for the wellhead based on the cluster centers of the multiple clustered machine learning models, a distance between the metocean conditions for the wellhead and null metocean conditions, and/or other information. For example, based on the metocean conditions for the wellhead not being similar to the training data used to train any clustered machine learning model and/or the metocean conditions for the wellhead not failing within or not being near any clusters of training data used to train the clustered machine learning models, the cluster centers of the multiple clustered machine learning models and the distance between the metocean conditions for the wellhead and null metocean conditions may be used to determine the wellhead fatigue damage rate for the wellhead. Rather than inputting the metocean conditions for the wellhead into a clustered machine learning model to determine the wellhead fatigue damage rate for the wellhead, the wellhead fatigue damage rate for the wellhead may be extrapolated from (1) the cluster centers of the multiple clustered machine learning models and (2) the distance between the metocean conditions for the wellhead and null metocean conditions. The cluster centers of the multiple clustered machine learning models may be associated with values of wellhead fatigue damage rate.

The null metocean conditions may refer to metocean conditions having or associated with the value zero. For example, the null metocean conditions may include no/zero wave and no/zero current for the wellhead. For instance, the null metocean conditions may include current speed of zero and significant wave height of zero. The null metocean conditions may be associated with no wellhead fatigue damage rate/zero value of wellhead fatigue damage rate.

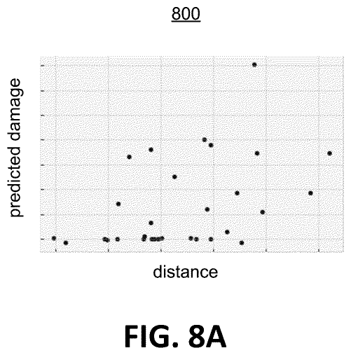

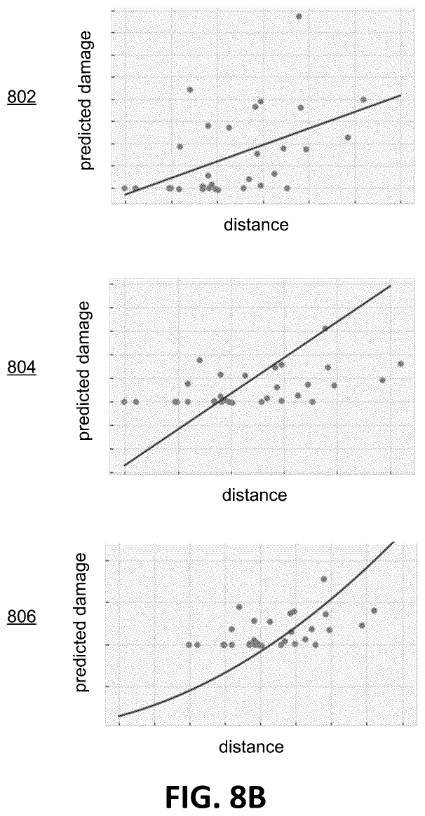

FIG. 8A illustrates example cluster centers for wellhead fatigue prediction. A plot 800 may show cluster centers of multiple clustered machine learning models. The cluster centers of multiple clustered machine learning models may correspond to/be same as the cluster centers of training data used to train the multiple clustered machine learning models. Individual cluster centers may be associated with (1) a distance from the null metocean conditions (x-value) and (2) predicted damage to the wellhead (e.g., predicated value of wellhead fatigue damage rate). The plot 800 may show a trend of increasing damage to the wellhead with increase in distance from the null metocean conditions. A positive relationship (e.g., linear relationship, non-linear relationship) may exist between the distance of metocean conditions from the null metocean conditions and the wellhead fatigue damage rate caused by the metocean conditions.

In some implementations, determination of the wellhead fatigue damage rate for the wellhead based on (1) the cluster centers of the multiple clustered machine learning models and (2) the distance between the metocean conditions for the wellhead and the null metocean conditions may include determination of one or more curves to fit the cluster centers of the multiple clustered machine learning models. The curve(s) may define wellhead fatigue damage rates as a function of distance from the null metocean conditions. The wellhead fatigue damage rate for the wellhead may be determined based on the curve(s) and the distance between the metocean conditions for the wellhead and the null metocean conditions. For example, the value of the curve(s) for the distance between the metocean conditions for the wellhead and the null metocean conditions may be output as the wellhead fatigue damage rate for the wellhead. The value of the curve(s) for the distance between the metocean conditions for the wellhead and the null metocean conditions may be used to determine the wellhead fatigue damage rate for the wellhead.

Use of the curve(s) and the distance between the metocean conditions for the wellhead and the null metocean conditions may enable accurate wellhead fatigue damage rate prediction for the wellhead despite the metocean conditions for the wellhead not being within training data for the multiple clustered machine learning models. With none of the clustered machine learning models trained to accurately perform wellhead fatigue damage rate prediction for particular metocean conditions, the curve(s) fit to the cluster centers of the multiple clustered machine learning models and the distance between the metocean conditions for the wellhead and the null metocean conditions may be used to accurately determine the wellhead fatigue damage rate. When the metocean conditions for the wellhead fall outside the training data for the multiple clustered machine learning models, the curve(s) fit to the cluster centers of the multiple clustered machine learning models and the distance between the metocean conditions for the wellhead and the null metocean conditions may be used to accurately determine the wellhead fatigue damage rate.

In some implementations, different curves may be generated for different scenarios of wellhead fatigue. For example, curves having different shapes may be fit to the cluster centers of the multiple clustered machine learning models, with different curves being used to predict wellhead fatigue damage rate of different wellheads/wells, different types of wellheads/wells, wellheads/wells in different locations, and/or wellheads/wells of different construction/materials.

FIG. 8B illustrates example curves that fit the cluster centers for wellhead fatigue prediction. Plots 802, 804, 806 show examples of three curves that fit the cluster centers of multiple clustered machine learning models. The curves may define different values of predicated damage to the wellhead (e.g., wellhead fatigue damage rate) as a function of distance from the null metocean conditions. The value of predicted damage to the wellhead that corresponds to the distance between the metocean conditions for the wellhead and the null metocean conditions may be output as the wellhead fatigue damage rate or to determine the wellhead fatigue damage rate.

In some implementations, determination of the wellhead fatigue damage rate for the wellhead may include monitoring the wellhead fatigue damage of the wellhead. For example, a real-time metocean conditions for the wellhead may be used to determine the present/real-time values of wellhead fatigue damage rate for the wellhead. The present/real-time values of wellhead fatigue damage rate for the wellhead may be tracked/accumulated to determine total wellhead fatigue damage over one or more durations of time. In some implementations, determination of the wellhead fatigue damage rate for the wellhead may include determination of historical wellhead fatigue damage rate for the wellhead for a period of time. For example, a historical metocean conditions for the wellhead may be used to determine the past values of wellhead fatigue damage rate for the wellhead for the period of time. In some implementations, determination of the wellhead fatigue damage rate for the wellhead may include forecasting of the wellhead fatigue damage rate for the wellhead for a future duration of time. For example, a forecast of metocean conditions for the wellhead may be used to predict values of wellhead fatigue damage rate for the wellhead for the future duration of time.

The operation component 112 may be configured to facilitate one or more well operations. A well operation may refer to an operation relating to a well. A well operation may refer to performance of work on and/or use of a well. A well operation may refer to an activity involving a well. A well operation may refer to an operation of a well in which the wellhead is installed/located. A well operation may refer to an operation of a well in which a riser is connected to the wellhead of the well. Facilitating a well operation may include making the well operation easier. Facilitating a well operation may include enabling, assisting in preparation, planning, and/or performance of the well operation. Other facilitations of well operations are contemplated.

The well operation(s) may be facilitated based on the wellhead fatigue damage rate for the wellhead and/or other information. The well operation(s) may be facilitated based on the wellhead fatigue damage rate for the wellhead and/or other information. The wellhead fatigued damage rate may be used to make operational decisions for the well/wellhead. The wellhead fatigued damage rate may be used to plan and/or perform well operations. For example, facilitation of a well operation based on the wellhead fatigue damage rate for the wellhead may include presentation of information relating to the wellhead fatigue damage rate on one or more displays, monitoring of the well operation based on information relating to the wellhead fatigue damage rate, planning of the well operation based on information relating to the wellhead fatigue damage rate, automation of the well operation based on information relating to the wellhead fatigue damage rate, and/or other facilitation of the well operation. Information relating to the wellhead fatigue damage rate may include the wellhead fatigue damage rate itself, information derived from the wellhead fatigue damage rate, and/or information from which the wellhead fatigue damage rate is derived. For example, information relating to the wellhead fatigue damage rate may include a wellhead fatigue damage accumulation, remaining allowable wellhead fatigue damage, and/or other information.

The wellhead fatigue damage accumulation may refer to an amount of fatigue damage accumulated at/experienced by the wellhead. The wellhead fatigue damage accumulation may refer to an amount of fatigue damage accumulated at/experienced by the wellhead for the entire time since the wellhead has been installed at the well. The wellhead fatigue damage accumulation may refer to an amount of fatigue damage accumulated at/experienced by the wellhead for a particular duration of time/particular operation. The wellhead fatigue damage accumulation may be determined based on the wellhead fatigue damage rate (e.g., real-time wellhead fatigue damage rate, past wellhead fatigue damage rate, forecasted wellhead fatigue damage rate) and the duration of time corresponding to the wellhead fatigue damage rate. For example, the amount of fatigue damage accumulation at the wellhead may be determined based on how long the wellhead was in operation (e.g., connected to the riser) and the estimated wellhead fatigue damage rate during the operation. As another example, amount of fatigue damage accumulation at the wellhead may be determined based on how long the wellhead was in operation and the real-time wellhead fatigue damage rate observed during the operation.

The remaining allowable wellhead fatigue damage may refer to how much additional fatigue damage may be accumulated at/experienced by the wellhead before failure or breakage of the wellhead is expected. The remaining allowable wellhead fatigue damage may indicate the remaining “life” of the wellhead. The remaining allowable wellhead fatigue damage may be determined based on the wellhead fatigue damage accumulation. The remaining allowable wellhead fatigue damage may be determined by subtracting the original allowable wellhead fatigue damage (e.g., 100% for a new wellhead; less than 100% for an existing wellhead) by the wellhead fatigue damage accumulation.

The remaining allowable wellhead fatigue damage may be determined for a particular duration of time/particular operation. For example, a specific operational event may be assigned a fatigue allowance. The fatigue allowance may refer to a limit on how much fatigue damage may be accumulated/experienced by the wellhead for a particular duration of time/particular operation. The fatigue allowance may refer to maximum allowable fatigue damage accumulation for a particular duration of time/particular operation. The remaining allowable wellhead fatigue damage for a particular duration of time/particular operation may be determined by subtracting the fatigue allowance for the particular duration of time/particular operation by the wellhead fatigue damage accumulation during the particular duration of time/particular operation. Other information relating to the wellhead fatigue damage rate is contemplated.

For example, the wellhead fatigue damage rate, the wellhead fatigue damage accumulation, and/or the remaining allowable wellhead fatigue damage may be presented on one or more displays. Real-time wellhead fatigue damage rate, past wellhead fatigue damage rate, and/or forecasted wellhead fatigue damage rate may be presented on the display(s). The wellhead fatigue damage rate may be presented with corresponding time durations. For example, forecasted wellhead fatigue damage rate may be presented along with the future duration (e.g., next 48 to 72 hours) in which the wellhead fatigue damage rate was forecasted. The wellhead fatigue damage accumulation since the installation of the wellhead and/or the wellhead fatigue damage accumulation for a particular duration of time/particular operation may be presented on the display(s). The remaining allowable wellhead fatigue damage for the life of the wellhead and/or the remaining allowable wellhead fatigue damage for a particular duration of time/particular operation may be presented on the display(s). Operators may plan and/or make operational decisions for the well based on the information presented. For example, information on the wellhead fatigue damage rate may be used to determine whether an operation should proceed or should be discontinued, such as by disconnecting the riser from the wellhead. Information on the wellhead fatigue damage rate may be used to perform reliability analysis, risk analysis, fatigue analysis, and/or fatigue simulation for the well/wellhead. Use of the present disclosure to generate information on the wellhead fatigue damage rate may be faster and less expensive in terms of computation, time, and/or cost than use of physics-based models.

In some implementations, facilitation of the well operation(s) based on the wellhead fatigue damage rate for the wellhead may include monitoring remaining allowable wellhead fatigue damage based on a wellhead fatigue damage accumulation and/or other information. The remaining allowable wellhead fatigue damage for the life of the wellhead and/or the remaining allowable wellhead fatigue damage for a particular duration of time/particular operation may be monitored. Monitoring the remaining allowable wellhead fatigue damage may include regularly calculating, checking, presenting, and/or otherwise monitoring the remaining allowable wellhead fatigue damage.

For example, monitoring the remaining allowable wellhead fatigue damage may include determining when the remaining allowable wellhead fatigue damage reaches one or more levels. Monitoring the remaining allowable wellhead fatigue damage may include determining when the remaining allowable wellhead fatigue damage is within a threshold value of one or more levels. Monitoring the remaining allowable wellhead fatigue damage may include presenting real-time values of remaining allowable wellhead fatigue damage on one or more displays. Monitoring the remaining allowable wellhead fatigue damage may include generating one or more alarms (e.g., more visual, audible, and/or haptic alarms) based on the remaining allowable wellhead fatigue damage reaching one or more levels/being within a threshold value of one or more levels.

In some implementations, one or more well operations may be performed/not performed based on Information relating to the wellhead fatigue damage rate. For example, an operation at a well may be stopped and the riser may be disconnected from the wellhead based on the remaining allowable wellhead fatigue damage reaching one or more levels/being within a threshold value of one or more levels. For instance, based on the remaining allowable wellhead fatigue damage for a particular operation reaching a certain level (e.g., a low value, 0%), the operation may be automatically stopped, and the riser may be disconnected from the wellhead to prevent further fatigue damage at the wellhead.

As another example, an operational event may be permitted or not permitted to proceed based on forecast of wellhead fatigue damage rate. An operational event may include one or more well operations. The forecast of wellhead fatigue damage rate may be used to determine a wellhead fatigue damage accumulation for the operational event. The wellhead fatigue damage accumulation for the operational event may be determined based on the duration of the operational event and the wellhead fatigue damage rate forecasted for the duration. The operational event may not be permitted to proceed based on the wellhead fatigue damage accumulation for the operational event exceeding the fatigue allowance for the operational event. The riser may be disconnected from the wellhead based on the wellhead fatigue damage accumulation for the operational event exceeding the fatigue allowance for the operational event.

On the other hand, the operational event may be permitted to proceed based on the wellhead fatigue damage accumulation for the operational event not exceeding the fatigue allowance for the operational event. Based on the forecast of wellhead fatigue damage accumulation for the operational event not exceeding the fatigue allowance for the operational event, the well operation(s) for the operational event may be permitted to proceed. Other control and/or automation of well operations based on information relating to the wellhead fatigue damage rate are contemplated.

Implementations of the disclosure may be made in hardware, firmware, software, or any suitable combination thereof. Aspects of the disclosure may be implemented as instructions stored on a machine-readable medium, which may be read and executed by one or more processors. A machine-readable medium may include any mechanism for storing or transmitting information in a form readable by a machine (e.g., a computing device). For example, a tangible computer-readable storage medium may include read-only memory, random access memory, magnetic disk storage media, optical storage media, flash memory devices, and others, and a machine-readable transmission media may include forms of propagated signals, such as carrier waves, infrared signals, digital signals, and others. Firmware, software, routines, or instructions may be described herein in terms of specific exemplary aspects and implementations of the disclosure, and performing certain actions.

In some implementations, some or all of the functionalities attributed herein to the system 10 may be provided by external resources not included in the system 10. External resources may include hosts/sources of information, computing, and/or processing and/or other providers of information, computing, and/or processing outside of the system 10.

Although the processor 11, the electronic storage 13, and the electronic display 14 are shown to be connected to the interface 12 in FIG. 1, any communication medium may be used to facilitate interaction between any components of the system 10. One or more components of the system 10 may communicate with each other through hard-wired communication, wireless communication, or both. For example, one or more components of the system 10 may communicate with each other through a network. For example, the processor 11 may wirelessly communicate with the electronic storage 13. By way of non-limiting example, wireless communication may include one or more of radio communication, Bluetooth communication, Wi-Fi communication, cellular communication, infrared communication, or other wireless communication. Other types of communications are contemplated by the present disclosure.

Although the processor 11, the electronic storage 13, and the electronic display 14 are shown in FIG. 1 as single entities, this is for illustrative purposes only. One or more of the components of the system 10 may be contained within a single device or across multiple devices. For instance, the processor 11 may comprise a plurality of processing units. These processing units may be physically located within the same device, or the processor 11 may represent processing functionality of a plurality of devices operating in coordination. The processor 11 may be separate from and/or be part of one or more components of the system 10. The processor 11 may be configured to execute one or more components by software; hardware; firmware; some combination of software, hardware, and/or firmware; and/or other mechanisms for configuring processing capabilities on the processor 11.

It should be appreciated that although computer program components are illustrated in FIG. 1 as being co-located within a single processing unit, one or more of computer program components may be located remotely from the other computer program components. While computer program components are described as performing or being configured to perform operations, computer program components may comprise instructions which may program processor 11 and/or system 10 to perform the operation.

While computer program components are described herein as being implemented via processor 11 through machine-readable instructions 100, this is merely for ease of reference and is not meant to be limiting. In some implementations, one or more functions of computer program components described herein may be implemented via hardware (e.g., dedicated chip, field-programmable gate array) rather than software. One or more functions of computer program components described herein may be software-implemented, hardware-implemented, or software and hardware-implemented.

The description of the functionality provided by the different computer program components described herein is for illustrative purposes, and is not intended to be limiting, as any of computer program components may provide more or less functionality than is described. For example, one or more of computer program components may be eliminated, and some or all of its functionality may be provided by other computer program components. As another example, processor 11 may be configured to execute one or more additional computer program components that may perform some or all of the functionality attributed to one or more of computer program components described herein.

The electronic storage media of the electronic storage 13 may be provided integrally (i.e., substantially non-removable) with one or more components of the system 10 and/or as removable storage that is connectable to one or more components of the system 10 via, for example, a port (e.g., a USB port, a Firewire port, etc.) or a drive (e.g., a disk drive, etc.). The electronic storage 13 may include one or more of optically readable storage media (e.g., optical disks, etc.), magnetically readable storage media (e.g., magnetic tape, magnetic hard drive, floppy drive, etc.), electrical charge-based storage media (e.g., EPROM, EEPROM, RAM, etc.), solid-state storage media (e.g., flash drive, etc.), and/or other electronically readable storage media. The electronic storage 13 may be a separate component within the system 10, or the electronic storage 13 may be provided integrally with one or more other components of the system 10 (e.g., the processor 11). Although the electronic storage 13 is shown in FIG. 1 as a single entity, this is for illustrative purposes only. In some implementations, the electronic storage 13 may comprise a plurality of storage units. These storage units may be physically located within the same device, or the electronic storage 13 may represent storage functionality of a plurality of devices operating in coordination.

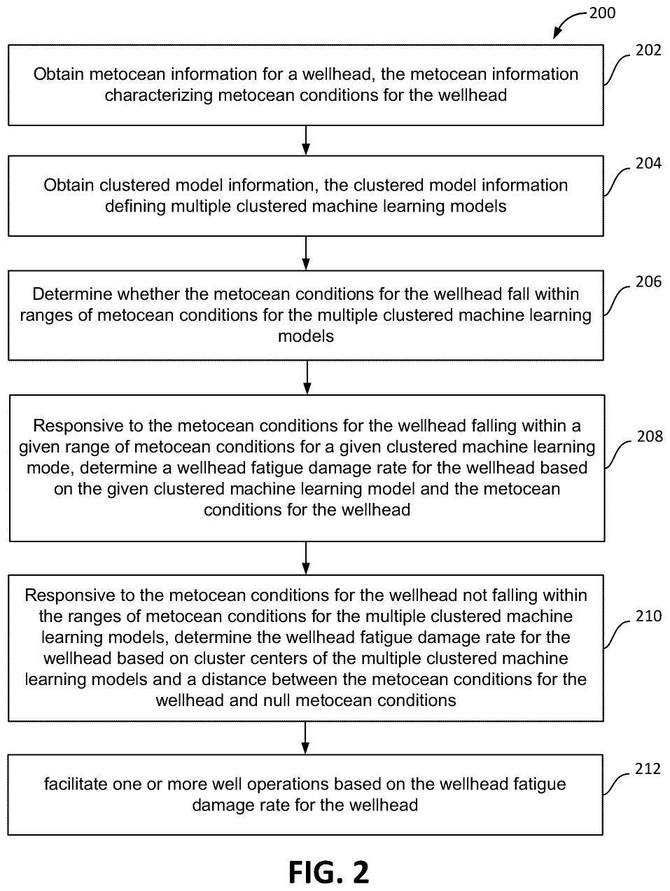

FIG. 2 illustrates method 200 for wellhead fatigue prediction. The operations of method 200 presented below are intended to be illustrative. In some implementations, method 200 may be accomplished with one or more additional operations not described, and/or without one or more of the operations discussed. In some implementations, two or more of the operations may occur substantially simultaneously.

In some implementations, method 200 may be implemented in one or more processing devices (e.g., a digital processor, an analog processor, a digital circuit designed to process information, a central processing unit, a graphics processing unit, a microcontroller, an analog circuit designed to process information, a state machine, and/or other mechanisms for electronically processing information). The one or more processing devices may include one or more devices executing some or all of the operations of method 200 in response to instructions stored electronically on one or more electronic storage media. The one or more processing devices may include one or more devices configured through hardware, firmware, and/or software to be specifically designed for execution of one or more of the operations of method 200.

Referring to FIG. 2 and method 200, at operation 202, metocean information for a wellhead may be obtained. The metocean information for the wellhead may characterize metocean conditions for the wellhead. In some implementations, operation 202 may be performed by a processor component the same as or similar to the metocean component 102 (Shown in FIG. 1 and described herein).

At operation 204, clustered model information may be obtained. The clustered model information may define multiple clustered machine learning models. The multiple clustered machine learning models may be trained for ranges of metocean conditions. The multiple clustered machine learning models may have cluster centers. In some implementations, operation 204 may be performed by a processor component the same as or similar to the clustered model component 104 (Shown in FIG. 1 and described herein).

At operation 206, whether the metocean conditions for the wellhead fall within the ranges of metocean conditions for the multiple clustered machine learning models may be determined. In some implementations, operation 206 may be performed by a processor component the same as or similar to the condition component 106 (Shown in FIG. 1 and described herein).

At operation 208, responsive to the metocean conditions for the wellhead falling within a given range of metocean conditions for a given clustered machine learning model, a wellhead fatigue damage rate for the wellhead may be determined based on the given clustered machine learning model, the metocean conditions for the wellhead, and/or other information. In some implementations, operation 208 may be performed by a processor component the same as or similar to the interpolation component 108 (Shown in FIG. 1 and described herein).

At operation 210, responsive to the metocean conditions for the wellhead not falling within the ranges of metocean conditions for the multiple clustered machine learning models, the wellhead fatigue damage rate for the wellhead may be determined based on the cluster centers of the multiple clustered machine learning models, a distance between the metocean conditions for the wellhead and null metocean conditions, and/or other information. In some implementations, operation 210 may be performed by a processor component the same as or similar to the extrapolation component 110 (Shown in FIG. 1 and described herein).

At operation 212, one or more well operations may be facilitated based on the wellhead fatigue damage rate for the wellhead and/or other information. In some implementations, operation 212 may be performed by a processor component the same as or similar to the operation component 112 (Shown in FIG. 1 and described herein).

Although the system(s) and/or method(s) of this disclosure have been described in detail for the purpose of illustration based on what is currently considered to be the most practical and preferred implementations, it is to be understood that such detail is solely for that purpose and that the disclosure is not limited to the disclosed implementations, but, on the contrary, is intended to cover modifications and equivalent arrangements that are within the spirit and scope of the appended claims. For example, it is to be understood that the present disclosure contemplates that, to the extent possible, one or more features of any implementation can be combined with one or more features of any other implementation.

What is claimed is:

1. A system for wellhead fatigue prediction, the system comprising:
one or more physical processors configured by machine-readable instructions to:
obtain metocean information for a wellhead, the metocean information characterizing metocean conditions for the wellhead;
obtain clustered model information, the clustered model information defining multiple clustered machine learning models, the multiple clustered machine learning models trained for ranges of metocean conditions, the multiple clustered machine learning models having cluster centers;
determine whether the metocean conditions for the wellhead fall within the ranges of metocean conditions for the multiple clustered machine learning models;
responsive to the metocean conditions for the wellhead falling within a given range of metocean conditions for a given clustered machine learning model, determine a wellhead fatigue damage rate for the wellhead based on the given clustered machine learning model and the metocean conditions for the wellhead;
responsive to the metocean conditions for the wellhead not falling within the ranges of metocean conditions for the multiple clustered machine learning models, determine the wellhead fatigue damage rate for the wellhead based on the cluster centers of the multiple clustered machine learning models and a distance between the metocean conditions for the wellhead and null metocean conditions; and
facilitate one or more well operations based on the wellhead fatigue damage rate for the wellhead.

2. The system of claim 1, wherein the metocean conditions for the wellhead include current profile and wave characteristics for the wellhead.

3. The system of claim 2, wherein:
the current profile for the wellhead includes speed and direction of water movement across a water column along a riser above the wellhead; and
the wave characteristics for the wellhead include peak wave period and significant wave height for wave above the water column.

4. The system of claim 1, wherein the null metocean conditions include no current and no wave.

5. The system of claim 1, wherein determination of whether the metocean conditions for the wellhead fall within the ranges of metocean conditions for the multiple clustered machine learning models includes:
determination of distances between the metocean conditions for the wellhead and the cluster centers of the multiple clustered machine learning models; and
determination of whether the metocean conditions for the wellhead fall within the ranges of metocean conditions for the multiple clustered machine learning models based on the distances between the metocean conditions for the wellhead and the cluster centers of the multiple clustered machine learning models.

6. The system of claim 1, wherein determination of the wellhead fatigue damage rate for the wellhead based on the given clustered machine learning model and the metocean conditions for the wellhead includes inputting the metocean conditions for the wellhead into the given clustered machine learning model, the given clustered machine learning model outputting the wellhead fatigue damage rate.

7. The system of claim 6, wherein use of the given clustered machine learning model for the determination of the wellhead fatigue damage rate for the wellhead enables higher accuracy in wellhead fatigue damage rate prediction than use of a universal machine learning model.

8. The system of claim 1, wherein determination of the wellhead fatigue damage rate for the wellhead based on the cluster centers of the multiple clustered machine learning models and the distance between the metocean conditions for the wellhead and the null metocean conditions includes:
determination of a curve to fit the cluster centers of the multiple clustered machine learning models, the curve defining wellhead fatigue damage rates as a function of distance from the null metocean conditions; and
determination of the wellhead fatigue damage rate for the wellhead based on the curve and the distance between the metocean conditions for the wellhead and the null metocean conditions.

9. The system of claim 8, wherein use of the curve and the distance between the metocean conditions for the wellhead and the null metocean conditions enables accurate wellhead fatigue damage rate prediction for the wellhead despite the metocean conditions for the wellhead not being within training data for the multiple clustered machine learning models.

10. The system of claim 1, wherein values of the metocean conditions for the wellhead are scaled and dimensionality of the metocean conditions for the wellhead are reduced.

11. A method for wellhead fatigue prediction, the method comprising:
obtaining metocean information for a wellhead, the metocean information characterizing metocean conditions for the wellhead;
obtaining clustered model information, the clustered model information defining multiple clustered machine learning models, the multiple clustered machine learning models trained for ranges of metocean conditions, the multiple clustered machine learning models having cluster centers;
determining whether the metocean conditions for the wellhead fall within the ranges of metocean conditions for the multiple clustered machine learning models;
responsive to the metocean conditions for the wellhead falling within a given range of metocean conditions for a given clustered machine learning model, determining a wellhead fatigue damage rate for the wellhead based on the given clustered machine learning model and the metocean conditions for the wellhead;
responsive to the metocean conditions for the wellhead not falling within the ranges of metocean conditions for the multiple clustered machine learning models, determining the wellhead fatigue damage rate for the wellhead based on the cluster centers of the multiple clustered machine learning models and a distance between the metocean conditions for the wellhead and null metocean conditions; and
facilitating one or more well operations based on the wellhead fatigue damage rate for the wellhead.

12. The method of claim 11, wherein the metocean conditions for the wellhead include current profile and wave characteristics for the wellhead.

13. The method of claim 12, wherein:
the current profile for the wellhead includes speed and direction of water movement across a water column along a riser above the wellhead; and
the wave characteristics for the wellhead include peak wave period and significant wave height for wave above the water column.

14. The method of claim 11, wherein the null metocean conditions include no current and no wave.

15. The method of claim 11, wherein determining whether the metocean conditions for the wellhead fall within the ranges of metocean conditions for the multiple clustered machine learning models includes:
determining distances between the metocean conditions for the wellhead and the cluster centers of the multiple clustered machine learning models; and
determining whether the metocean conditions for the wellhead fall within the ranges of metocean conditions for the multiple clustered machine learning models based on the distances between the metocean conditions for the wellhead and the cluster centers of the multiple clustered machine learning models.

16. The method of claim 11, wherein determining the wellhead fatigue damage rate for the wellhead based on the given clustered machine learning model and the metocean conditions for the wellhead includes inputting the metocean conditions for the wellhead into the given clustered machine learning model, the given clustered machine learning model outputting the wellhead fatigue damage rate.

17. The method of claim 16, wherein use of the given clustered machine learning model for the determination of the wellhead fatigue damage rate for the wellhead enables higher accuracy in wellhead fatigue damage rate prediction than use of a universal machine learning model.

18. The method of claim 11, wherein determining the wellhead fatigue damage rate for the wellhead based on the cluster centers of the multiple clustered machine learning models and the distance between the metocean conditions for the wellhead and the null metocean conditions includes:
determining a curve to fit the cluster centers of the multiple clustered machine learning models, the curve defining wellhead fatigue damage rates as a function of distance from the null metocean conditions; and
determining the wellhead fatigue damage rate for the wellhead based on the curve and the distance between the metocean conditions for the wellhead and the null metocean conditions.

19. The method of claim 18, wherein use of the curve and the distance between the metocean conditions for the wellhead and the null metocean conditions enables accurate wellhead fatigue damage rate prediction for the wellhead despite the metocean conditions for the wellhead not being within training data for the multiple clustered machine learning models.

20. The method of claim 11, wherein values of the metocean conditions for the wellhead are scaled and dimensionality of the metocean conditions for the wellhead are reduced.
